(19) United States
(12) Patent Application Publication
(10) Pub. No.: US 2002/0000569 A1
(43) Pub. Date: Jan. 3, 2002

(54) Charge coupled device type solid state pickup apparatus an method of operating the same

(76) Inventor: Sang-Il Jung, Seoul (KR)

Correspondence Address: JONES VOLENTINE, L.L.C., Suite 150, 12200 Sunrise Valley Drive, Reston, VA, 20191, US

(21) Appl. No.: 09/862,304

(22) Filed: May 23, 2001

(30) Foreign Application Priority Data
May 23, 2000 (KR) 2000-27808

(51) Int. Cl. H01L 31/0328

(52) U.S. Cl. 257/183

(57) ABSTRACT

A solid state pickup apparatus is described, which can weaken a dark current. The pickup apparatus includes an optical shield layer with a number of windows corresponding to the light receiving parts, and a negative voltage applying device. Each of the light receiving parts has a solid state pickup device where an P-type diode layer is formed between an N-type diode layer and a gate insulating layer. The negative voltage applying device is formed at the optical shield layer in order to apply a negative voltage to the P-type diode layer.

This application relies for priority upon Korean Patent Application No. 2000-27808, filed on May 23, 2000, the contents of which are herein incorporated by reference in their entirety.

### BACKGROUND OF THE INVENTION

The present invention relates to a solid state pickup apparatus using a charge coupled device (CCD). More particularly, the present invention relates to a solid state pickup apparatus that can weaken a dark current and a method of operating the same.

In a solid state pickup apparatus, a solid state pickup device is a key semiconductor device that senses and changes external images into image signals. The pickup device converts into signals external images that are illuminated by an objective lens in each pixel. The converted image signals are then amplified and transmitted by the pickup device, and are reconstructed in a display apparatus such as television.

With reference to FIG. 1 and FIG. 2, a basic planar construction of a solid state pickup apparatus will now be described. FIG. 1 is a top plan view showing a planar structure of a conventional CCD-type solid state pickup device. FIG. 2 is a cross-sectional view taken along a line II-II′ of FIG. 1, which shows a vertical structure at a part where a light receiving part of an N-type diode layer buried solid-state pickup device is coupled to a transmission unit.

As shown in FIG. 1, a regular flat area (usually a foursquare area) of a semiconductor substrate is surrounded by an insulation part (not shown) in which a field insulating layer is formed. A number of light receiving parts 13 are constructed having a matrix shape in the surrounded part. Generally, each of the light receiving parts 13 includes a photodiode.

Vertical transmission units 15, which are constructed between the light receiving parts 13, are formed parallel with each column. One end of each of the vertical transmission units 15 are commonly coupled to a horizontal transmission unit 17 that is perpendicular to the vertical transmission units 15.

An optical shield layer 19 is formed over the solid state pickup device. The optical shield layer has a window 11 that exposes the light receiving part 13 to allow a light to be incident only upon the photodiode in the light receiving part 13.

In this device, light is generally condensed by a micro lens (not shown), which is located over the solid state pickup device, and an optical lens in a camera. In many cases, incident light is not perpendicular to the light receiving part, but rather has a lower angle of incidence. For this reason, the optical shield layer 19 is formed to overlap with a peripheral part of the photodiode by a constant width.

In addition, a voltage applying device 16, which is usually grounded, is connected to the optical shield layer 19.

In basic construction, each of the light receiving parts 13 is identical to a photodiode with a unit P-N junction. For example, a P-type impurity diode layer is formed over a surface layer of a semiconductor substrate, while a buried N-type impurity diode layer is formed beneath it. The N-type impurity diode layer is surrounded by P-type impurity layers so that it will be isolated.

As shown in FIG. 2, a window 11 surrounded by the optical shield layer 19 is formed over a light receiving part. A P-type diode layer 25, an N-type diode layer 27, a P-type well 29, and an N-type substrate 20 are formed in downwardly-progressing layers under the light receiving part. The P-type diode layer 25 is doped with P⁺ impurities, while the N-type diode layer 27 is doped with ⁻ impurities. The P-type diode layer 25 is a surface layer of a receiving part photodiode and is separated from the optical shield layer 19 by an insulating layer 23.

Beside the light receiving part, a transmission unit 24 is covered by the optical shield layer 19. In this area, an electrode 21, the transmission unit 24, a P-type doping layer 28, the P-type well 29, and the N-type substrate 20 are formed in downwardly-progressing layers below the optical shield layer 19.

A channel layer 26 is formed between the transmission unit 24 and the N-type photodiode layer 27. And an insulating layer 23 is formed to insulate the optical shield layer 19 from the gate electrode 23.

If the photodiode formed in the light receiving part 13 senses external light, it generates photoelectrons to condense charges. The condensed charges are then transmitted to a corresponding area of the vertical transmission unit 15 through a channel by an externally-applied clock signal. The transmitted charges sent to the vertical transmission unit 15 are gradually transmitted to the horizontal transmission unit 17 by a clock signal that is applied to the vertical transmission unit 15. The transmitted charges to the horizontal transmission unit 17 are then transmitted to a circuit of an output unit by a clock signal that is rapidly applied to the horizontal transmission unit 17, thus generating an amplified image signal.

FIG. 3 illustrates the voltage change along the line III-III′ in FIG. 2. This area represents a vertical construction of a solid state pickup device at photodiode areas that are formed in a light receiving part 13. Specifically, FIG. 3 shows the voltages being applied to each of the areas shown along the X-axis in FIG. 3.

In FIG. 3, the X-axis denotes a vertical distance from a surface of the optical shield layer 19 to the solid state device substrate 20, while the Y-axis denotes a voltage. The optical shield layer 19 and the P-type diode layer 25 are both grounded, so that a zero voltage are applied to them. The N-type diode layer 27 and the P-type well 29 compose a depletion area. A voltage of the N-type diode layer 27 has a positive value caused by donor ions. Even though the P-type well 29 is grounded, it has a positive voltage. A constant voltage +V (e.g., 10 V) is applied to a lower part of an N-type substrate layer 20.

The P-type well 29 has a lower voltage than the N-type diode layer 27 and the N-type substrate layer 20. Accordingly, the P-type well 29 serves as a voltage barrier between these two layers. A voltage applied to the substrate layer 20 can control a voltage of the P-type well 29, and a quantity of electric charge that is condensed in the N-type diode layer 27. This makes it possible to prevent a blooming phenomenon that results in image distortion caused by overcharge.

If the light receiving photodiode receives light, an electron-hole pair (EHP) is created to transfer electrons to the N-type diode layer 27. The transferred electrons are blocked at the P-type well 29, by being condensed in the N-type diode layer 27. In operation, a hole flows into the grounded P-type diode layer 25. The EHP is created by light or heat (preferably, “by light” in view of performance of a solid state pickup device).

In capturing an image of a dark place, a screen must be displayed with a dark image. In such an image some EHPs are created by heat, even though there is little incident light. Electrons in these EHPs are condensed in the N-type diode 27 and are transmitted through a transmission unit (i.e., the vertical transmission unit 15 and the horizontal transmission unit 17), with the result that they are displayed as a signal to form relatively bright points in the screen. The current caused by these electrons that are created by heat is called a dark current. The relatively bright points caused by the dark current are called white points.

A main source of an EHP created by heat is a dangling bond that is located on a surface of a silicon layer. Since electrons created in the dangling bond flow into the N-type diode layer 27, it is necessary to prevent screen distortion by blocking the dark current that is made by these electrons.

According to a conventional design, a P-type diode layer 25 is inserted between the interface with a surface of a silicon layer (i.e., the insulating layer 23) and the N-type diode layer 27. When electrons created by a dangling bond are condensed in the high voltage N-type diode layer 27, they pass through the P-type diode layer 25. Many holes of the P-type diode layer 25 are recombined with the electrons that are created in the dangling bond. Accordingly, the number of the condensed electrons is reduced to prevent creation of the white points, and so the dark current is weakened.

Nevertheless, since other holes remain in the P-type diode layer 25, which is a kind of a depletion area, it is still impossible to prevent the electrons that pass through the P-type diode layer 25 and are condensed in the N-type diode layer 27.

### SUMMARY OF THE INVENTION

It is an object of the present invention to provide a charge coupled device type solid state pickup apparatus and method of operating the same that can weaken a dark current and reduce or eliminate a white point phenomenon resulting from electrons that are created in a dangling bond of a silicon layer surface.

It is another object of the invention to provide a solid state pick apparatus that can prevent a dark current and screen distortion resulting from the dark current without changing a conventional method of forming a solid state pickup device.

According to an aspect of the invention, a charge coupled device type solid state pickup apparatus is provided. The solid state pickup apparatus comprises a light receiving part having a solid state pickup device in which a P-type diode layer is formed between an N-type diode layer and a gate insulating layer; a vertical transmission unit connected to the light receiving part; a horizontal transmission unit connected to the vertical transmission unit; a gate electrode for transmitting charges; a conductive optical shield formed over the light receiving parts, having a window corresponding to the light receiving part; a peripheral circuit for applying at least a first voltage to the solid state pickup device; and a negative voltage applying device for applying a second voltage to the optical shield, wherein the second voltage is a negative voltage.

The voltage applying device may be a part of the peripheral circuit, and is preferably a fixed voltage applying device.

The second voltage is preferably obtained from a negative voltage clock signal applied to the gate electrode. Furthermore, The second voltage is preferably between −5 V and −9 V.

A solid state pickup apparatus preferably includes a plurality of photodiodes in a foursquare area that is isolated by field insulating layers. The pickup apparatus includes a number of matrix-arranged light receiving parts, vertical transmission units that are parallel with each column of the matrix, and a horizontal transmission unit that is commonly coupled to one edge of all the vertical transmission units. A gate electrode is formed at the pickup device in order to transmit charges. A voltage of a predetermined pattern is applied to the gate electrode through a peripheral circuit part, transmitting the charges. A solid state pickup device, which has been covered with the insulating layers, is covered with a conductive optical shield layer that has a window formed over a light receiving part.

The solid state pickup device has an N-type diode layer that is buried in a light receiving part of the photodiode area. To construct the pickup apparatus, a circuit part for applying a voltage is combined with each terminal of the pickup apparatus. One manner to apply the negative voltage is to select one negative voltage among some clock signal level voltages which are applied to the vertical transmission unit and to apply it to the optical shield layer.

A method is provided of operating a charge coupled device type solid state pickup apparatus. This method comprises continuously applying a first voltage to a terminal in the solid state pickup apparatus; and continuously applying a second voltage of a constant level to a terminal of an optical shield in the solid state pickup apparatus, wherein the second voltage is a negative voltage.

The second voltage is preferably obtained from a negative voltage clock signal applied to a vertical transmission unit in the solid state pickup device, and is preferably between −5 V and −9 V.

According to another aspect of the invention, there is provided a method of operating a solid state pickup apparatus. Using a power and a peripheral circuit part to which electrodes of solid state pickup devices composing the pickup apparatus are connected, a voltage of a predetermined pattern is applied to each of the electrodes. A negative voltage is applied to an optical shield layer, which is then shot.

### BRIEF DESCRIPTION OF THE DRAWINGS

FIG. 1 is a top plan view showing a planar structure of a conventional CCD-type solid state pickup device.

FIG. 2 is a cross-sectional view taken along a line II-II′ of FIG. 1, which shows a vertical structure at a part where a light receiving part of an N-type diode layer buried solid-state pickup device is coupled to a transmission unit.

FIG. 3 is a graph showing the voltage change and applied voltages along a line III-III′ of FIG. 2, according to a conventional design.

FIG. 4 is a graph showing voltage change and applied voltages along a the line III-III′ of FIG. 2, according to a preferred embodiment of the present invention.

FIGS. 5A and 5B are graphs comparing the yields of a solid state pickup device according to a conventional design and the preferred embodiment of the present invention, in proportion to sizes of white points in a display device.

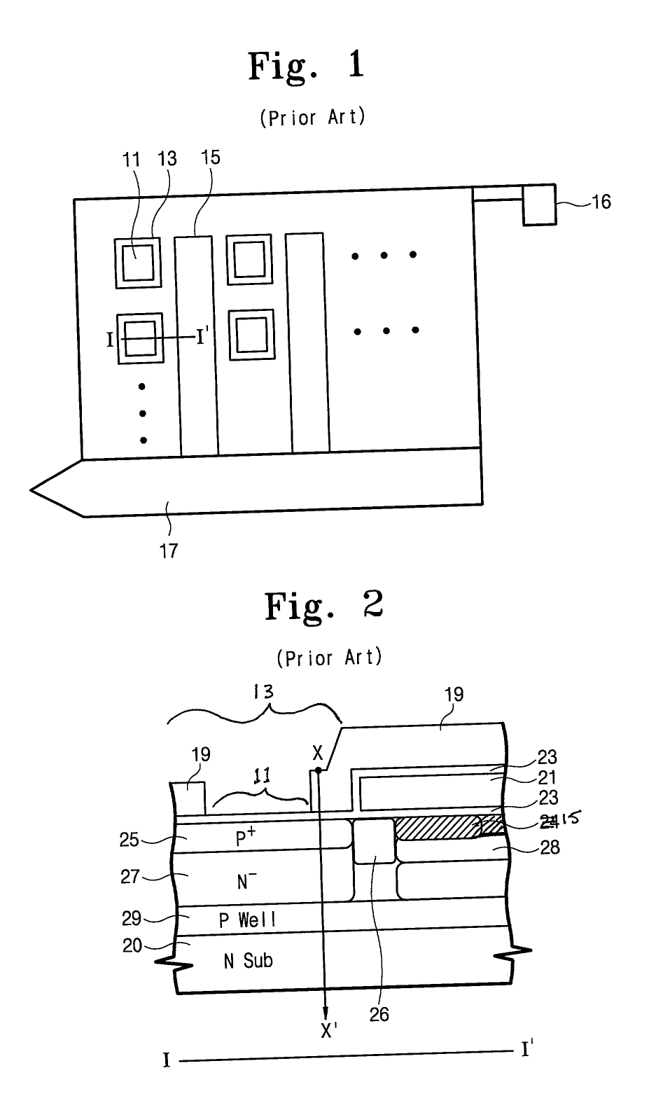

### DESCRIPTION OF THE PREFERRED EMBODIMENT

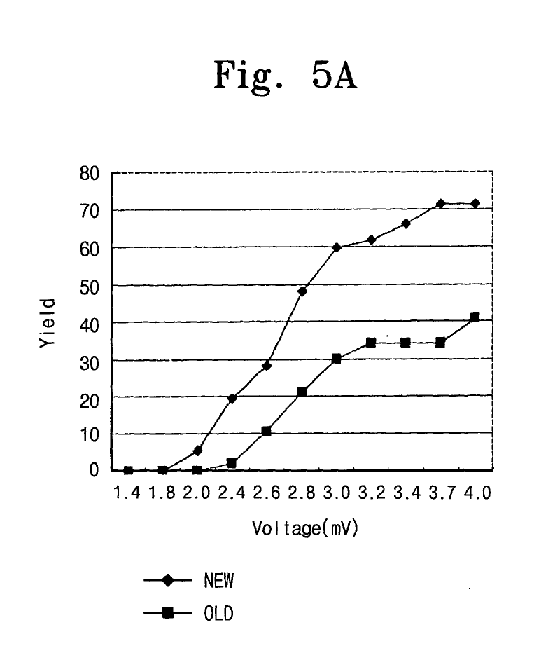

FIG. 4 illustrates a voltage change from a surface of an optical shield layer to a rear side of a substrate at a light receiving part 13 of a solid state pickup device according a preferred embodiment of to the present invention.

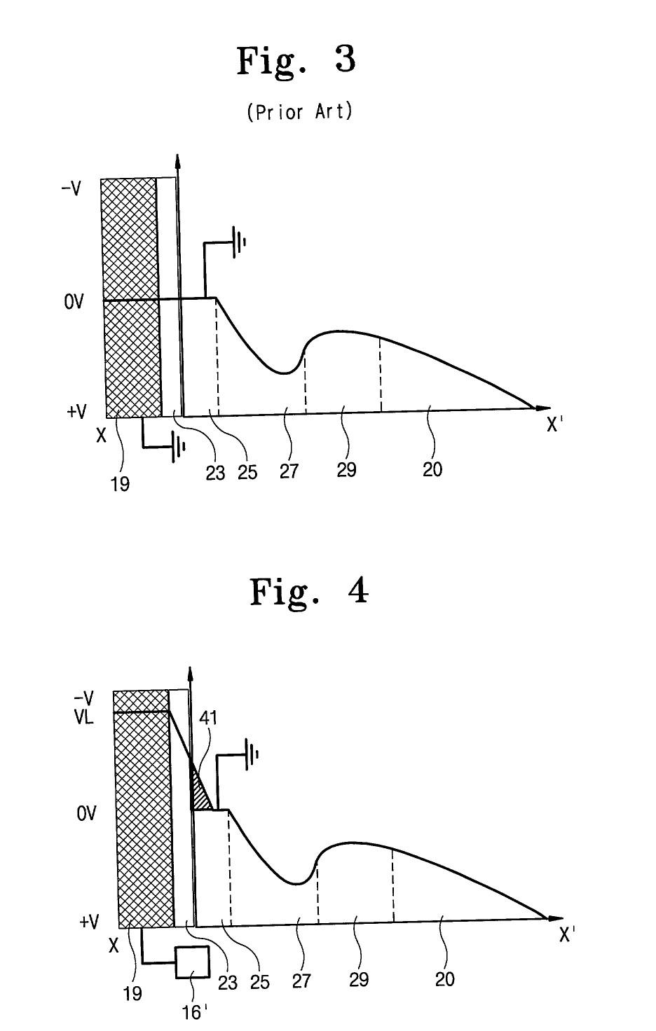

Comparing FIG. 3 and FIG. 4, features of the present invention will become apparent. A conventional voltage applying device 16 connected to an optical shield layer 19 is changed to a negative voltage applying device 16′, which provides a constant negative voltage V_{L}. As a result, the ground voltage applied to the optical shield layer 19 in the conventional design is changed to the constant negative voltage V_{L}.

Since the insulating layer 23 is formed between the optical shield layer 19 and the P-type diode layer 25, an electric potential difference between the ground voltage and V_{L} is distributed to the insulating layer 23. In this way, a negative voltage weakened from an interface is also applied to the P-type diode layer 25.

In operation, a number of holes are condensed in an area to which the negative voltage is applied. In other words, the holes, which generally flow into a ground connected to the p type diode layer 25 in the prior art structure, are conducted to a negative voltage of the p type diode layer 25 in the present invention. Accordingly, many holes exist in an interface part of the p type diode layer 25 to the insulating layer 23.

As in the conventional design, in the pickup apparatus of this preferred embodiment of the present invention, an electron-hole pair (EHP) may be created at the silicon interface part by a thermal excitation phenomenon. The EHP then flows into the N-type diode layer 27 where electrons have a high voltage. When the electrons are induced to the N-type diode 27, they pass through the P-type diode layer 25 where a number of holes are collected. The passing electrons are then recombined with these holes, erasing or weakening any dark current.

An erase efficiency of the dark current can be enhanced because a potential becomes lowest because of the negative voltage applied to the optical shield layer 19 and a density of holes becomes highest, particularly, at a non-coupling part. As a result, an dark current is weakened, which reduces or attenuates the white points of a display image. This avoids any distortion of the image and improves image quality.

FIG. 4 illustrates a voltages along the line III-III′ from FIG. 2. The white point phenomenon does not pertain only to a light receiving part from a pixel. A dark current can be generated at a semiconductor by a thermal excitation, but may also be generated at a non-light receiving part. Especially, a vertical or horizontal transmission unit of a solid state pickup device where N-type impurity layers like the layer 25 in FIG. 2 are formed under the insulating layer (or the silicon oxide layer) has a great influence upon dark current.

A dark current of a transmission unit transmits a failed image signal to a display device together with the dark current that is generated at the light receiving part, causing a distorted image to be displayed. If electrons of the light receiving part are not transmitted to the vertical transmission unit 15 and a charge is only transmitted to the horizontal transmission unit 17, a dark current generated by the vertical transmission unit 15 can be measured. If the dark current that is generated by the vertical transmission unit 15 is subtracted from the total current, a dark current from only the light receiving part 13 can be determined.

In an impurity doping structure, the transmission unit is different from the light receiving part. Accordingly, even though the voltage V_{L} is applied, the transmission unit may not have an effect same as the light receiving part 13. Nevertheless, a negative voltage is applied to the whole shield layer 19 in the transmission unit and the light receiving part 13, integrating holes and removing hot electrons at a part that is not shielded by a conductive layer.

The following tables (TABLE 1 and TABLE 2) show a strength of a dark current when an optical shield terminal 19 of one solid state pickup device is grounded (i.e. has a zero voltage) and when it has a negative voltage applied (V_{L}). In general, when the voltage VL is applied to the optical shield terminal 19, the dark current is reduced to be 80% smaller than a conventional design. As can be seen below, the dark currents at the transmission unit as well as at the light receiving part photodiode area are weakened by the novel structure of this invention.

TABLE 1
Dark Current at First Pilot Production Line

| | Optical | Optical | Optical | Optical |
|---|---|---|---|---|
| | shield at | shield at | shield at | Shield |
| Source of | Voltage V_{L} | Voltage V_{L} | Grounded | Grounded |
| Dark current | (Sample 1-1) | (Sample 1-2) | (Sample 1-1) | (Sample 1-2) |
| Photodiode | 0.1 mA | 0.11 mA | 0.22 mA | 0.18 mA |
| Element | | | | |
| Transmission | 1.27 mA | 1.26 mA | 1.57 mA | 1.5 mA |
| Unit Element | | | | |

TABLE 2
Dark Current at Second Pilot Production Line

| | Optical | Optical | Optical | Optical |
|---|---|---|---|---|
| | shield at | shield at | shield | Shield |
| Source of | Voltage V_{L} | Voltage V_{L} | Grounded | Grounded |
| Dark current | (Sample 2-1) | (Sample 2-2) | (Sample 2-1) | (Sample 2-2) |
| Photodiode | 0.15 mA | 0.16 mA | 0.2 mA | 0.21 mA |
| Element | | | | |
| Transmission | 1.29 mA | 1.33 mA | 1.62 mA | 1.63 mA |
| Unit Element | | | | |

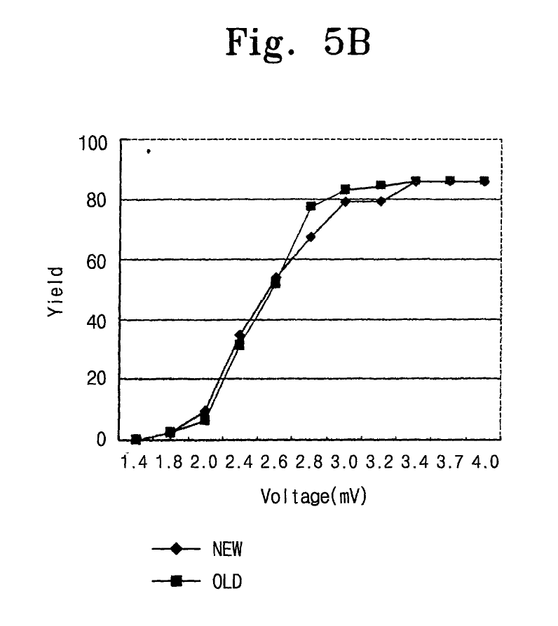

FIG. 5A and FIG. 5B are graphs showing yields according to a strength of voltages corresponding to the white points. That is, the voltages in these graphs are the standard voltages allowable for the white point phenomenon. If the standard voltage is high, the boundary of allowance is broad. The yields are based on operating result of the solid state pickup apparatus according to the preferred embodiment of the invention. As shown in FIG. 5A, compared with operating a conventional solid state pickup apparatus, a yield is higher in nearly all ranges of voltage.

As shown in FIG. 5B, a yield is similar in nearly all ranges. With reference to FIG. 5A and FIG. 5B, it is understood that the present invention can stabilize the yield of the solid state pickup apparatus. In other words, there is a great difference between a good or bad yield based on a white point in a conventional design, while a constant yield can be achieved in the present invention.

As explained above, using a solid state pickup apparatus and a method of operating a solid state pickup device in accordance with the present invention, a dark current in CCD-type solid state pickup apparatus can be weakened without a increased overhead. Furthermore, a white point phenomenon on a display device screen and visibility are reduced, which enhances screen quality.

It is to be understood that this invention is not limited to the particular forms illustrated and that it is intended in the appended claims to cover all modifications that do not depart from the spirit and scope of this invention.

What is claimed is:

1. A charge coupled device type solid state pickup apparatus, comprising:
a light receiving part having a solid state pickup device in which a P-type diode layer is formed between an N-type diode layer and a gate insulating layer;
a vertical transmission unit connected to the light receiving part;
a horizontal transmission unit connected to the vertical transmission unit;
a gate electrode for transmitting charges; and
a conductive optical shield formed over the light receiving parts, having a window corresponding to the light receiving part;
a peripheral circuit for applying at least a first voltage to the solid state pickup device; and
a voltage applying device for applying a second voltage to the optical shield,
wherein the second voltage is a negative voltage.

2. A charge coupled device type solid state pickup apparatus, as recited in claim 1, wherein the voltage applying device is a part of the peripheral circuit.

3. A charge coupled device type solid state pickup apparatus, as recited in claim 1, wherein the second voltage is obtained from a negative voltage clock signal applied to the vertical transmission unit.

4. A charge coupled device type solid state pickup apparatus, as recited in claim 1, wherein the voltage applying device is a fixed voltage applying device.

5. A charge coupled device type solid state pickup apparatus, as recited in claim 1, wherein the second voltage is between −5 V and −9 V.

6. A method of operating a charge coupled device type solid state pickup apparatus, comprising:
continuously applying a first voltage to a terminal in the solid state pickup apparatus; and
continuously applying a second voltage of a constant level to a terminal of an optical shield in the solid state pickup apparatus,
wherein the second voltage is a negative voltage.

7. The method of claim 6, wherein the second voltage is obtained from a negative voltage clock signal applied to a vertical transmission unit in the solid state pickup device.

8. The method of claim 6, wherein the negative voltage is between −5 V and −9 V.
